(19) United States
(12) Patent Application Publication
(10) Pub. No.: US 2012/0225519 A1
(43) Pub. Date: Sep. 6, 2012

(54) PREPARATION OF SOLAR MODULES

(75) Inventors: Hubert Ehbing, Odenthal (DE); Gunther Stollwerck, Krefeld (DE)

(73) Assignee: Bayer MaterialScience AG, Leverkusen (DE)

(21) Appl. No.: 13/498,225

(22) PCT Filed: Sep. 30, 2010
(86) PCT No.: PCT/EP2010/064534

§ 371 Date: Apr. 30, 2012

(30) Foreign Application Priority Data
Oct. 1, 2009 (DE) 102209047906.6

(51) Int. Cl. H01L 31/18

(52) U.S. Cl. 438/73; 257/E31.001

(57) ABSTRACT

The present invention relates to a method for the production of solar modules, in which air inclusions are prevented.

The present invention relates to a process for the preparation of solar modules in which air inclusions are avoided.

Solar modules are construction elements for the direct generation of electricity from sunlight. Key factors for a cost-efficient generation of solar electricity include the efficiency of the solar cells employed as well as the production cost and durability of the solar modules.

A solar module usually consists of a framed composite of glass, interconnected solar cells, an encapsulation material and a backside construction. The individual layers of the solar module serve the following functions.

The front glass serves for protection from mechanical impact and the effects of the weather. It must have an excellent transparency in order to keep absorption losses in the optical spectral range of from 300 nm to 1150 nm and thus efficiency losses of the silicon solar cells, which are usually employed for power generation, as low as possible. Normally, tempered low-iron white glass (3 or 4 mm thick), whose transmittance in the above spectral range is around 90 to 92%, is used. Further, the glass significantly contributes to the rigidity of the module.

The encapsulating material (mostly EVA (ethylene-vinyl acetate) sheets) serves for adhesively bonding the whole module assembly. During a lamination process, EVA melts at about 150° C., flows into the spaces of the soldered solar cells and is cross-linked by a thermally initiated chemical reaction. The formation of air bubbles, which would result in reflection losses, is avoided by lamination under vacuum.

The backside of the module protects the solar cells and the encapsulating material from moisture and oxygen. In addition, it serves as a mechanical protection from scratch etc. when the solar modules are mounted, and as an electrical insulation. Another sheet of glass or a composite sheet can be employed as the backside construction. Mostly, the variants PVF(polyvinyl fluoride)-PET(polyethylene terephthalate)-PVF or PVF-aluminum-PVF are employed.

In particular, the encapsulating materials employed on the backside in solar module construction must have good barrier properties against humidity and oxygen. Humidity and oxygen do not attack the solar cells themselves, but corrosion of the metal contacts and chemical degradation of the EVA encapsulating material occur. A destroyed solar cell contact leads to complete failure of the module since normally all solar cells in one module are electrically serially connected. A degradation of the EVA can be seen from a yellowing of the module associated with a corresponding performance reduction by light absorption and visual deterioration.

Today, about 80% of all modules are encapsulated on the backside with one of the composite sheets described, and glass is used for the front and back sides of about 15% of the solar modules. In this case, in part highly transparent casting resins, which cure slowly, however (several hours), may be employed as encapsulating material instead of EVA.

In order to achieve competitive electricity generation costs of solar electricity despite the relatively high investment cost, solar modules must reach long service lives. Therefore, solar modules are designed for a service life of 20 to 30 years today. In addition to a high weather stability, high demands are placed on the temperature resistance of the modules, whose temperature can vary cyclically during operation from 80° C. under full solar irradiation to temperatures below the freezing point. Accordingly, solar modules are subjected to extensive stability tests (standard tests according to IEC 61215 and IEC 61730), which include weather tests (UV irradiation, damp heat, temperature cycling), but also hail impact test and tests of the electric insulation performance.

Module finishing accounts for 30% of the total cost for photovoltaic modules, which is a relatively large proportion. This large proportion of module fabrication is due to high material costs (for example, backside multilayer sheet) and long process times, i.e., low productivity. The above described individual layers of the module composite are frequently still manually assembled and oriented. In addition, the relatively slow melting of the EVA hot-melt adhesive and the lamination of the module composite at about 150° C. under vacuum cause cycle times of about 20 to 30 minutes per module.

Due to the relatively thick front glass sheet, conventional solar modules additionally have a high weight, which in turn necessitates stable support constructions, which are expensive. Also, the problem of heat dissipation is unsatisfactorily solved in current solar modules. Upon full solar irradiation, the modules will heat up to 80° C., which results in a temperature-induced deterioration of the solar cell efficiency and thus ultimately in solar electricity becoming more expensive.

In the prior art, solar modules are mainly used with a frame of aluminum. Although aluminum is a light metal, its weight contributes substantially to the total weight. Just with larger modules, this is a drawback that requires expensive support and attachment constructions.

In order to prevent the ingress of water and oxygen, said aluminum frames have an additional seal on their interior side facing towards the solar module. In addition, there is another disadvantage in that aluminum frames are prepared from rectangular profiles, so that their shapes are severely limited.

To reduce the solar module weight, to avoid an additional sealing material and to increase the freedom of design, U.S. Pat. No. 4,830,038 and U.S. Pat. No. 5,008,062 describe the provision of a plastic frame around the corresponding solar module, the frame being obtained by the RIM (reaction injection molding) process.

Preferably, the polymeric material employed is an elastomeric polyurethane. Said polyurethane preferably has a modulus of elasticity within a range of from 200 to 10,000 psi (corresponding to about 1.4 to 69.0 N/mm²).

Various possibilities for reinforcing the frame are described in these two patent specifications. Thus, reinforcing components made of, for example, a polymeric material, steel or aluminum can be integrated with the frame when the latter is formed. Also, fillers can be included in the frame material. These may be, for example, plate-like fillers, such as the mineral wollastonite, or acicular/fibrous fillers, such as glass fibers.

Similarly, DE 37 37 183 A1 also describes a process for the preparation of the plastic frame of a solar module, the Shore hardness of the material employed preferably being adjusted to ensure a sufficient rigidity of the frame and an elastic accommodation of the solar generator.

The above described modules are erected by means of support constructions or applied, for example, to roof structures. They thus require some rigidity of the module, which is brought about disadvantageously by a (plastic) frame and the relatively heavy front glass panel, which has a thickness of about 3 to 4 mm. In addition, the front glass panel causes some absorption merely because of its thickness, which in turn has disadvantageous effects on the efficiency of the solar module.

In so-called thin-film modules, solar cells are embedded between two plastic films, or else between a front-side transparent plastic film and a flexible metal plate (aluminum or stainless steel) on the backside. For example, sheet laminates of the trademark “UNIsolar®” consist of an amorphous silicon thin-film vapor-deposited on a thin stainless steel plate, embedded between two plastic sheets. Subsequently, such flexible laminates must be adhesively bonded to a rigid support structure, such as metal roofing elements or roofing elements made of metal sandwich composites. DE 10 2005 032 716 A1 describes a flexible solar module that must be subsequently applied to a rigid support structure. A disadvantage thereof is the additional process step, i.e., the subsequent adhesive bonding to a support structure.

Due to the different coefficients of thermal expansion of the plastic frame and the glass, delaminations and ingress of moisture into the interior region of the solar module occurred again and again in the past, which ultimately resulted in the module being destroyed.

From US 2003/178056 A1, a solar cell module is known comprising first and second protective layers, the solar cells being sealed between these two layers. An insulating sheet made of a plastic material is placed between the second, moisture-proof layer and the solar cells. The second, moisture-proof layer comprises sheets including a metal foil. An aluminum, iron or zinc foil is used as said metal foil.

A weather-resistant film for sealing a photovoltaic module is additionally known from DE 102 31 401 A1. The weather-resistant layer is constituted of several polymer layers, wherein a moisture-proof layer of aluminum, electroplated steel, silica, titania or zirconia is additionally present between the polymer layers. A corresponding photovoltaic module is prepared by laminate construction.

Further, a photovoltaic module and a process for the preparation thereof are described in EP 1 302 988 A2. It describes a specific adhesive layer made of an aliphatic thermoplastic polyurethane. The solar cells are embedded in this hot-melt adhesive layer. Further, the solar module contains a cover plate and a backsheet.

One possible preparation method is lamination by means of a roll laminator. In a first step, a laminate is prepared from a covering plate or sheet and an adhesive film in a roll laminator. In a second step, a cover/adhesive film composite, solar strings, and a backsheet/adhesive film composite are introduced on top of one another in another roll laminator. The three individual components are bonded together in said roll laminator. This requires the three components to be exactly registered.

A process for preparing a solar module having a low weight coupled with a high rigidity us described in the as yet unpublished PCT application PCT/EP2009/003951. The solar module has a backside consisting of a sandwich element. Such a sandwich element includes a core layer and outer layers attached to it. The outer layers, which are made of a fiber-reinforced plastic material, provide the element with a high rigidity. Because of the core layer having a honeycomb structure, the sandwich element has a low weight.

This application mentions several methods for preparation, all of which describe a layered construction. Thus, in one method, the sandwich element is provided first. Subsequently, the adhesive layer, solar cells, optionally another adhesive layer, and a transparent layer in the form of a glass panel or a plastic layer are applied across the whole surface. Then, the whole layer assembly is pressed together. In an alternative method, a transparent plastic film bearing an adhesive layer is provided first. Subsequently, the solar cells and the sandwich element are applied across the whole surface, and the whole layer assembly is pressed together.

In such a layered construction of a solar cell, air inclusions may occur between the sandwich element and the transparent layer facing a light source, especially when large-area solar cells are prepared. The application of the sandwich element as a final layer causes air to be trapped in the composite material. Since neither the transparent layer that will face the light source during operation nor the sandwich element is permeable to air, this air cannot be sufficiently removed by either pressing together the composite under a high pressure, or applying a vacuum.

Therefore, it is an object of the present invention to provide a process for the preparation of solar modules that avoids the drawbacks of the prior art.

The solar module is to have as low a weight per unit area as possible and at the same time be as flexurally rigid as possible, so that no support or attachment structure, or only a very simple one, is required, and the module can be handled without difficulty. Further, the solar module should have a sufficient composite long-term stability, which prevents delaminations and/or the ingress of moisture.

This object is achieved by a process according to the invention. Therefore, the invention relates to a process for preparing a solar module (10) comprising a sandwich element (6), one or more solar cells (3) embedded in an adhesive layer (2), and a transparent layer (1) that will face a light source during operation, characterized in that

in a first step, a first composite (7) is prepared from a sandwich element (6) comprising at least one core layer (5) and at least one outer layer (4) present on either side of the core layer (5), and an adhesive layer (2b);

in a second layer, a second composite (8) comprising the transparent layer (1), an adhesive layer (2a) and at least one solar cell (3) is prepared; and

in a third step, the composites from the first and second steps are bonded to each other through the respective adhesive surfaces.

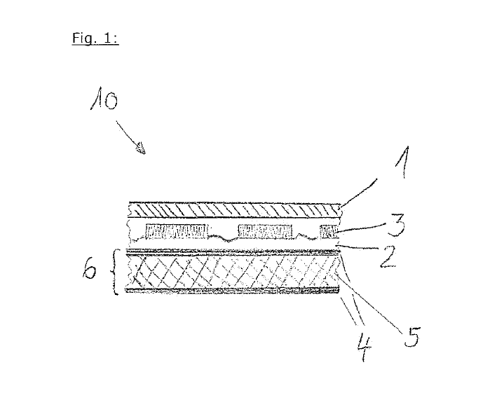

The invention is illustrated in FIGS. 1 to 3 and described more concretely in the following.

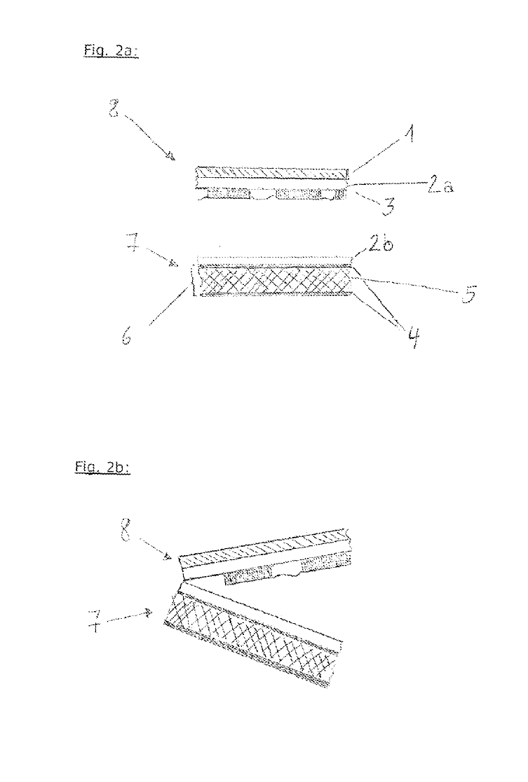

A process according to the invention, in which a first composite (7) is prepared from a sandwich element (6) and an adhesive layer (2b) applied to one of the outer layers (4), and separately at first, a second composite (8) comprising said at least one solar cell (3), which is bonded through as adhesive layer (2a) to a transparent layer (1) that will face a light source during operation, is prepared in a separate second step, as shown in FIG. 2a, makes it possible that no air is trapped in the final product when the two composites are joined together through the adhesive surfaces. This is enabled by the fact that said sandwich element (6) is not applied across the whole surface through adhesive layer (2b) to a composite (8) comprising the transparent layer (1), the solar cell (3) and the adhesive layer (2a). Rather, in the process according to the invention as shown in FIG. 2b, it is possible to join the two separately prepared composites (7) and (8) at one end (edge), bonding the two composites (7) and (8) together from this end towards the other end. The two adhesive layers (2a) and (2b) may consist of the same or different materials. When the composites (7) and (8) are bonded together, they form a unitary adhesive layer (2) in the finished solar module (10).

In addition, it is also possible to bond composites (7) and (8) together optionally under the influence of temperature, and/or optionally with application of a vacuum. In particular, it is possible to bond composites (7) and (8) together in a continuous process, for example, by employing a roll laminator as described in EP 1 302 998 A1.

Thus, a process according to the invention enables the preparation of a solar module (10) according to FIG. 1, which has sufficient stability because of the sufficient flexural strength of sandwich element (6). Because of its sufficiently high rigidity, the solar module (10) is easily handled and will not sag even after extended periods of time. The composite long-term stability of such a composite is also excellent, since the difference of the coefficient of thermal expansion of the sandwich element (6) as compared to that of the transparent layer (1) and that of the solar cells is very low. Therefore, mechanical stresses hardly occur, and the risk of delamination is very low.

In the solar module (10) prepared according to the invention, the sandwich element (6) further serves to seal the solar module (10) against external influences.

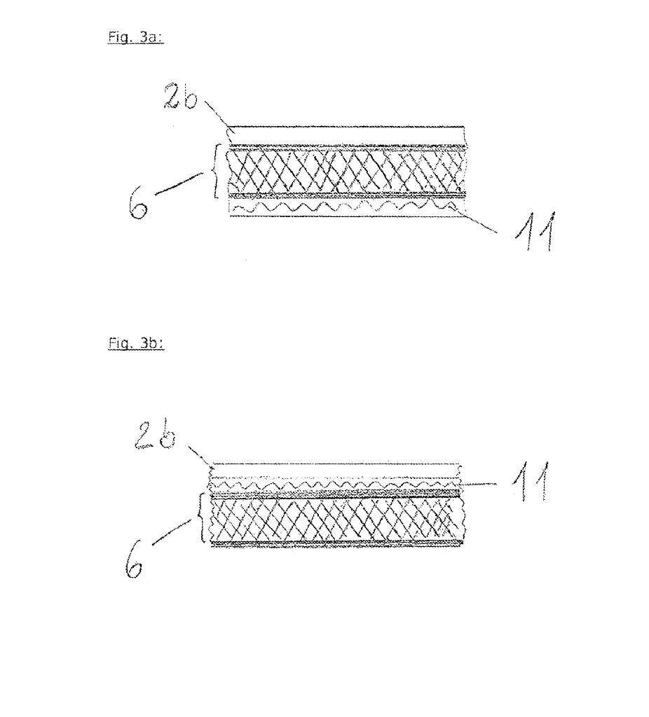

With an additional barrier layer (11), for example, in the form of a barrier sheet, this seal can be additionally improved. Preferably, it is directly applied during the preparation of the sandwich element (6), and may be present either on the side of the sandwich element (6) facing away from adhesive layer (2) (FIG. 3a), or between adhesive layer (2b) and sandwich element (6) (FIG. 3b). According to the invention, a sandwich element (6) comprises at least one core layer (5) as well as at least one outer layer (4) on either side of core layer (5).

Suitable materials that may be employed for core layer (5) of the sandwich element (6) include, for example, rigid foams, preferably polyurethane (PUR) or polystyrene foams, balsa woods, corrugated metal sheets, spacers (for example, of large-pore open-cell plastic foams), honeycomb structures made of, for example, metals, soaked papers or plastics, or sandwich core materials known from the prior art (e.g., Klein, B., Leichtbau-Konstruktion, Verlag Vieweg, Braunschweig/Wiesbaden, 2000, pages 186 ff.). More preferred are formable, especially thermoformable, rigid foams (e.g., PUR rigid foams) and honeycomb structures, which enable a domed or three-dimensional design of the solar module (10) to be produced.

Especially for the preparation of solar modules that are to simultaneously serve a building-insulating function as roofing and/or facade materials, in particular, rigid foams with good insulation properties are further preferred. The element, especially the core layer (5), also serves for insulation, especially thermal insulation.

Suitable rigid foams include, for example, polyurethane rigid foams of the type Baynat 81IF60B/Desmodur VP.PU 0758 from the company Bayer MaterialScience AG with a bulk density of 30 to 150 kg/m³, preferably 40 to 120 kg/m³, more preferably 50 to 100 kg/m³ (measured according to DIN EN ISO 845). These rigid foams have an open-pore fraction of ≧10%, preferably ≧12%, more preferably ≧15% (measured according to DIN EN ISO 845), a compression strength of ≧0.2 MPa, preferably ≧0.3 MPa, more preferably ≧0.4 MPa (measured in a compression test according to DIN EN 826) and a modulus of elasticity in compression of ≧6 MPa, preferably ≧8 MPa, more preferably ≧10 MPa (measured in a compression test according to DIN EN 826).

The outer layers (4) are, in particular, fibrous layers provided on both sides of the core layer (5) that are soaked, for example, with a resin, especially a polyurethane resin.

The polyurethane resin that may be employed, for example, is obtainable by reacting:
i) at least one polyisocyanate;
ii) at least one polyol component with an average OH number of from 300 to 700, which includes at least one short-chain and one long-chain polyol, the starting polyols having a functionality of 2 to 6;
iii) water;
iv) activators;
v) stabilizers;
vi) optional auxiliary agents, mold release agents and/or additives.

Suitable long-chain polyols preferably include polyols having at least two to mostly six isocyanate-reactive H atoms; preferably employed are polyester polyols and polyether polyols having OH numbers of from 5 to 100, preferably from 20 to 70, more preferably from 28 to 56. Suitable short-chain polyols preferably include those having OH numbers of from 150 to 2000, preferably from 250 to 1500, more preferably from 300 to 1100.

According to the invention, higher-nuclear isocyanates of the diphenylmethane diisocyanate series (pMDI types), prepolymers thereof of mixtures of such components are preferably employed. Water is employed in amounts of from 0 to 3.0, preferably from 0 to 2.0, parts by weight on 100 parts by weight of polyol formulation (components ii) to vi)).

The per se usual activators for the chain-propagation and cross-linking reactions, such as amines or metal salts, are used for catalysis. Polyether siloxanes, preferably water-soluble components, are preferably used as foam stabilizers. The stabilizers are usually applied in amounts of from 0.01 to 5 parts by weight, based on 100 parts by weight of the polyol formulation (components ii) to vi)).

To the reaction mixture for preparing the polyurethane resin, there may optionally be added auxiliary agents, mold release agents and additives, for example, surface-active additives, such as emulsifiers, flame retardants, nucleating agents, antioxidants, lubricants, mold release agents, dyes, dispersants, blowing agents, and pigments.

The components are reacted in such amounts that the equivalent ratio of the NCO groups of the polyisocyanates i) to the sum of the isocyanate-reactive hydrogens of components ii) and iii) and optionally iv), v) and vi) is from 0.8:1 to 1.4:1, preferably from 0.9:1 to 1.3:1.

As the fibrous material for the fibrous layers, there may be employed glass fiber mats, glass fiber webs, glass fiber random fiber mats, glass fiber fabric, chopped or ground glass or mineral fibers, natural fiber mats and knits, chopped natural fibers, as well as fibrous mats, webs and knits based on polymer, carbon and aramid fibers, as well as mixtures thereof.

The production of the sandwich elements (6) can be effected by first applying a fibrous layer to both sides of the core layer (5), which is then impregnated with the polyurethane starting components i) to vi).

Alternatively or additionally, a fiber reinforcing material may also be introduced along with the polyurethane raw materials using a suitable mixing head technique. The thus prepared blank consisting of the three layers is transferred to a mold, and the mold is closed. The reaction of the PUR components bonds the individual layers together.

The sandwich element (6) is characterized by a low weight per unit area of from 1500 to 4000 g/m² and a high flexural rigidity of from 0.5 to 5×10⁶ N/mm² (based on 10 mm width of sample). In particular, the sandwich element (6) has a substantially lower weight per unit area for a comparable flexural rigidity as compared to other support structures made of plastic materials or metals, such as plastic blends (polycarbonate/acrylonitrile-butadiene-styrene, polyphenylene oxide/polyamide), sheet molding compound (SMC), or aluminum and steel plates.

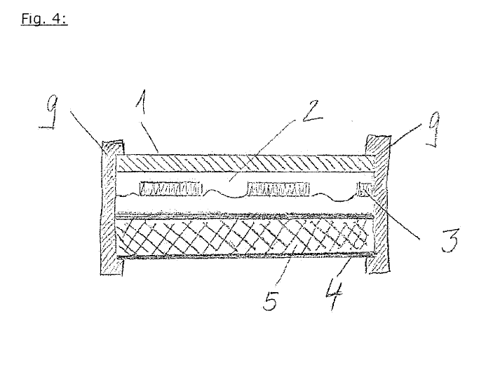

As mentioned above, such a sandwich element (6) serves to seal the solar module (10) against external influences. However, the core layer (5) of the sandwich element (6) itself, in particular, is at risk from weather influences, especially moisture. Therefore, in a process according to the invention, a circumferential plastic material (9) is applied to a finished solar module (10). This plastic material preferably consists of reinforced, especially glass-fiber reinforced, polyurethanes. FIG. 4 shows a corresponding module.

The “reinforced polyurethane”, and especially that of the circumferential plastic material (9), means PUR containing fillers for reinforcement. Preferably, the fillers are synthetic or natural, especially mineral, fillers. More preferably, the fillers are selected from the group consisting of mica, plate-like and/or fibrous wollastonite, glass fibers, carbon fibers, aramid fibers, or mixtures thereof. Among these fillers, fibrous wollastonite is preferred because it is inexpensive and readily available.

Preferably, the fillers additionally have a coating, especially an aminosilane-based coating. In this case, the interaction between the fillers and the polymer matrix is enhanced. This results in better performance characteristics since the coating permanently couples the fibers to the polyurethane matrix.

The fillers are typically dispersed in the polyol charge. For example, the circumferential plastic material (9) is injected around the finished solar module (10) by the R-RIM method as known from the prior art. Thus, the finished solar module (10) is placed into a mold, and the frame (9) is injected around the solar module (10).

The polyurethanes employed for the frame (9) according to the invention are obtainable, for example, by reacting

a) organic di- and/or polyisocyanates with

b) at least one polyether polyol having a number average molecular weight of from 800 g/mol to 25,000 g/mol, preferably from 800 to 14,000 g/mol, more preferably from 1000 to 8000 g/mol, and having an average functionality of from 2.4 to 8, more preferably from 2.5 to 3.5; and

c) optionally further polyether polyols other than b) having a number average molecular weight of from 800 g/mol to 25,000 g/mol, preferably from 800 to 14,000 g/mol, more preferably from 1000 to 8000 g/mol, and having average functionalities of from 1.6 to 2.4, preferably from 1.8 to 2.4; and

d) optionally polymer polyols having filler contents of from 1 to 50% by weight, based on the polymer polyol, and having OH numbers of from 10 to 149 and average functionalities of from 1.8 to 8, preferably from 1.8 to 3.5; and

e) optionally chain extenders having average functionalities of from 1.8 to 2.1, preferably 2, and having molecular weights of 750 g/mol and less, preferably from 18 g/mol to 400 g/mol, more preferably from 60 g/mol to 300 g/mol, and/or cross-linking agents having average functionalities of from 3 to 4, preferably 3, and having molecular weights of up to 750 g/mol, preferably from 18 g/mol to 400 g/mol, more preferably from 30 g/mol to 300 g/mol;

f) in the presence of amine catalysts; and

g) metal catalysts; and

h) optionally additives, especially flame retardants.

Preferably, these polyurethanes are prepared by the prepolymer method, in which a polyaddition adduct having isocyanate groups is appropriately prepared from at least part of the polyether polyol b) or a mixture thereof with polyol component c) and/or d) and at least one di- or polyisocyanate a) in the first step. In the second step, solid PUR elastomers can be prepared from such prepolymers having isocyanate groups by reacting them with low molecular weight chain extenders and/or cross-linking agents e) and/or the remainder of the polyol components b) and optionally c) and/or d). If water of other blowing agents or mixtures thereof are included in the second step, microcellular PUR elastomers can be prepared.

Suitable starting components a) include aliphatic, cycloaliphatic, araliphatic, aromatic and heterocyclic polyisocyanates as described, for example, by W. Siefken in Justus Liebigs Annalen der Chemie, 562, pages 75 to 136.

Because of their higher hydrolytic stability, polyether polyols are particularly preferred as component b).

The fastening of the solar module (10) to the respective substrate (for example, roofs or walls of houses) can be effected through either the sandwich element (6) or the circumferential plastic material (9). Therefore, according to the invention, the solar module (10) preferably includes pre-integrated fastening means, recesses and/or holes in the sandwich element (6) or the circumferential plastic material (9), which can be used to effect the fastening. Further, the sandwich element (6) preferably includes the electric connection elements, so that a later attachment of, for example, connection sockets can be omitted.

The transparent layer (1) that will face a light source during operation in the finished solar module (10) may be made of the following materials: glass, polycarbonate, polyester, poly(methyl methacrylate), polyvinyl chloride, fluorine-containing polymers, epoxides, thermoplastic polyurethanes, or any combinations of such materials. Further, transparent polyurethanes based on aliphatic isocyanates may also be used. HDI (hexamethylene diisocyanate), IPDI (isophorone diisocyanate) and/or H12-MDI (saturated methylenediphenyl diisocyanate) are employed as isocyanates. Polyethers and/or polyester polyols are employed as the polyol component, and chain extenders are used, aliphatic systems being preferably used.

The transparent layer (1) may be embodied as a plate, plastic sheet or composite sheet. Preferably, a transparent protective layer may be applied to the transparent layer (1), for example, in the form of a paint or plasma layer. The transparent layer (1) could be made softer by such a measure, which may further reduce stresses in the module. The additional protective layer would take up the protection against external influences.

The adhesive layer (2) preferably has the following properties: a high transparence within a range of from 350 nm to 1150 nm, and a good adhesion to silicon and to the material of the transparent layer, and to the sandwich element (6). The adhesive layer (2) is soft in order to compensate for stresses caused by the different coefficients of thermal expansion of the transparent layer (1), solar cells and sandwich element (6). The adhesive layer (2) is a transparent plastic layer. It is made of, for example, EVA, polyethylene or silicon rubber; preferably, it is made of a thermoplastic polyurethane, which may be provided with colorants in the case of the layer (2) facing away from the light.

In a further embodiment, fluid conduits can be co-molded during the preparation of the sandwich element (6). Such conduits may be made of, for example, plastic or copper. Preferably, such conduits are located close to the adhesive layer (2) and can be used for cooling the solar module (10) by a heat-transfer fluid (e.g., water). Interior cooling of the solar module (10) can be used to increase the electrical efficiency.

The solar modules (10) prepared according to the invention generate electricity and at the same time act as an insulating layer, so that they may well be utilized as roofing elements. They are very lightweight and at the same time rigid. They can also be converted to three-dimensional structures by pressing, so that they are readily adapted to given roof structures.

Further, solar modules (10) prepared according to the invention are suitable for use as facade elements. Because of their design, they are readily adapted to corresponding surface structures.

Thus, the thin-film solar laminate consists, for example, of a transparent front layer, an adhesive layer (for example, EVA, TPU, PE, transparent plastics functionalized with adhesion promoters), and solar cells provided behind.

Both parts, the sandwich element and the thin-film solar laminate, are bonded together, for example, in a vacuum laminator.

An advantage of this method is the fact that the preparation of the sandwich element is separated from the preparation of the thin-film solar laminate. The preparation of a sandwich element, which is preferably based on polyurethane, can be done, for example, by spraying. However, this has the disadvantage that spray particles may get onto the sheet laminate and stain the solar module or detrimentally affect its function.

This is prevented by decoupling the two process steps, also in space. In addition, advantages in productivity result because the sandwich element can be introduced as a prefabricated part into the solar module manufacturing process according to the prior art.

### EXAMPLES

### Example 1

A solar module was prepared from the following individual components.

To prepare a thin-film solar laminate, a 125 μm thick polycarbonate film (type Makrofol® DE 1-4 of Bayer Material Science AG, Leverkusen) was used as the front layer. A 480 μm thick TPU film (type Vistasolar® of the company Etimex, Rottenacker, Germany) served as the hot-melt adhesive layer. The individual components in the order of polycarbonate film, TPU film and 4 silicon solar cells were superposed to form a laminate, evacuated in a vacuum laminator (NPC, Tokyo, Japan) at 150° C. for 6 minutes at first, and subsequently compressed under a pressure of 1 bar for 7 minutes to form a thin-film solar laminate.

A Baypreg® sandwich was used as the sandwich element. Thus, a random fiber mat of type M 123 having a weight per unit area of 300 g/m² (from the company Vetrotex, Herzogenrath, Germany) was laid on both sides of a paper honeycomb of type Testliner 2 (A wave, honeycomb thickness 4.9-5.1 mm, from the company Wabenfabrik, Chemnitz). Subsequently, 300 g/m² of a reactive polyurethane system was sprayed on both sides of this structure using a high-pressure processing machine.

A polyurethane system from Bayer MaterialScience AG, Leverkusen, consisting of a polyol (Baypreg® VP.PU 01IF13) and an isocyanate (Desmodur® VP.PU 08IF01) was used at a mixing ratio of 100 to 235.7 (index 129).

The assembly of the paper honeycomb and the random fiber mats sprayed with polyurethane was transferred into a compression mold on the bottom of which there had been previously inserted a TPU sheet (480 μm, type Vistasolar® from the company Etimex, Rottenacker, Germany). The mold was temperature-controlled at 130° C., and the assembly was compressed for 90 seconds to give a 10 mm thick sandwich.

The individual components in the assembly of thin-film solar laminate and Baypreg® sandwich were laid together evacuated in a vacuum laminator (NPC, Tokyo, Japan) at 150° C. for 6 minutes at first, and subsequently compressed under a pressure of 1 bar for 7 minutes to form a solar module.

### Example 2

By analogy with Example 1, a random fiber mat of type M 123 having a weight per unit area of 300 g/m² (from the company Vetrotex, Herzogenrath, Germany) was laid on both sides of a polyurethane rigid foam plate of the type Baynat (system Baynat 81IF60B/Desnnodur VP.PU 0758 from the company Bayer MaterialScience AG (thickness 10 mm, bulk density 66 kg/m³ (measured according to DIN EN ISO 845), open-pore fraction 15.1% (measured according to DIN EN ISO 845), modulus of elasticity in compression of ≧6 MPa, preferably ≧8 MPa, more preferably ≧10 MPa (measured in a compression test according to DIN EN 826), modulus of elasticity in compression (measured according to DIN EN 826) of 11.58 MPa, and compression strength of 0.43 MPa (measured according to DIN EN 826) for preparing the sandwich element. Subsequently, 300 g/m² of a reactive polyurethane system was sprayed on both sides of this structure using a high-pressure processing machine. A polyurethane system from Bayer MaterialScience AG, Leverkusen, consisting of a polyol (Baypreg® VP.PU 01IF13) and an isocyanate (Desmodur® VP.PU 08IF01) was used at a mixing ratio of 100 to 235.7 (index 129).

The assembly of a polyurethane rigid foam plate and the random fiber mats sprayed with polyurethane was also transferred into a compression mold on the bottom of which there had been previously inserted a TPU sheet (480 μm, type Vistasolar® from the company Etimex, Rottenacker, Germany). The mold was temperature-controlled at 130° C., and the assembly was compressed for 90 seconds to give a 10 mm thick sandwich.

1-9. (canceled)

10. A process for preparing a solar module (10), the process comprising:
preparing a first composite (7) comprising a sandwich element (6), having at least one core layer (5) and at least one outer layer (4) present on either side of the core layer (5), and a first adhesive layer (2b);
preparing a second composite (8) comprising a transparent layer (1), a second adhesive layer (2a) and at least one solar cell (3) is prepared; and then
bonding together the first composite to the second composite by adhering the respective adhesive layers together.

11. The process according to claim 10, wherein bonding together the first and second composites takes place under the influence of temperature and/or with application of a vacuum.

12. The process according to claim 10, wherein bonding together the first and second composites is performed continuously.

13. The process according to claim 10, further comprising providing a circumferential plastic material (9) around the bonded composites.

14. The process according to claim 10, wherein said transparent layer (1) is a glass pane or a plastic layer.

15. The process according to claim 10, wherein said adhesive layer (2) is a thermoplastic polyurethane.

16. The process according to claim 10, wherein the at least one core layer (5) comprises a rigid foam, balsa woods, corrugated metal sheets, spacers or honeycomb structures made of metals, soaked papers or plastics.

17. The process according to claim 16, wherein said outer layer (4) is a fiber-reinforced polyurethane.
